(19) United States
(12) Patent Application Publication
(10) Pub. No.: US 2016/0002775 A1
(43) Pub. Date: Jan. 7, 2016

(54) MULTILAYER LINER FOR CHEMICAL VAPOR DEPOSITION FURNACE

(71) Applicant: Rolls-Royce Corporation, Indianapolis, IN (US)

(72) Inventor: Kang N. Lee, Zionsville, IN (US)

(21) Appl. No.: 14/788,067

(22) Filed: Jun. 30, 2015

Related U.S. Application Data
(60) Provisional application No. 62/020,287, filed on Jul. 2, 2014.

(51) Int. Cl. C23C 16/44; B05D 7/00; B32B 15/04

(52) U.S. Cl. CPC C23C 16/4404; B32B 15/04; B05D 7/54; C23C 16/4409

(57) ABSTRACT

A multilayer liner for a chemical vapor deposition furnace may include a first layer comprising graphite and a second layer comprising a metal or alloy. The first layer may define an internal surface of the multilayer liner, and the multilayer liner may define a substantially closed internal volume. In some examples, the metal or alloy may be the same as a metal or alloy that is in a substrate to be coated within an internal volume of the multilayer liner.

### RELATED APPLICATIONS

This application claims the benefit of U.S. Provisional Application No. 62/020,287, titled, “MULTILAYER LINER FOR CHEMICAL VAPOR DEPOSITION FURNACE,” filed Jul. 2, 2014, the entire content of which is incorporated herein by reference.

### TECHNICAL FIELD

The disclosure relates to liners for chemical vapor deposition furnaces.

### BACKGROUND

Chemical vapor deposition (CVD) processes may be used to deposit coatings on substrates. CVD processes may be dynamic or static. In a dynamic CVD process, the coating process occurs in an open system. The substrate to be coated is placed inside a retort and heated to a predetermined temperature. The coating precursor is placed in a separate chamber and reacted with an activator, such as a halide activator, to form a coating gas. The coating gas flows through a conduit from the chamber to the retort, where the coating gas reacts with the substrate to deposit the coating.

In a static CVD technique, the coating process occurs in a closed system. The substrate to be coated, the coating precursor, and an activator are placed inside a sealed retort, which is then purged using a vacuum pump and backfilled with an inert gas. The contents of the sealed retort are then heated, and the coating precursor and activator react to form a coating gas, which reacts with the substrate to be coated to form the coating.

### SUMMARY

The disclosure describes a multilayer liner for a CVD furnace. In some examples, the multilayer liner may include a graphite layer and a metal or alloy layer. In some examples, the metal or alloy layer may include an element included in the substrate-to-be-coated. For example, the metal or alloy layer may include the element on which the substrate is based (e.g., the element present in the substrate in the largest concentration). The combination of the graphite layer and the metal or alloy layer may reduce or substantially prevent a contaminant species from the furnace from being incorporated in the coating formed during the CVD process, e.g., compared to a liner including only one of a graphite layer or a metal or alloy layer.

In contrast to a crucible, which is open to the surrounding atmosphere within the CVD furnace, the multilayer liner may define an internal volume that is substantially closed to the atmosphere within the CVD furnace. Further, when the furnace is heated during the CVD process, the solid coating materials present within the volume defined by the multilayer liner vaporize, forming a positive pressure within the volume defined by the multilayer liner compared to the internal volume of the CVD furnace. This may reduce movement of gas from within the CVD furnace and outside of the internal volume of the multilayer liner into the internal volume of the multilayer liner, reducing or substantially eliminating incorporation of one or more elements from the furnace being incorporated into the coating.

In some examples, the disclosure describes a multilayer liner for a chemical vapor deposition furnace, the multilayer liner comprising a first layer comprising graphite and a second layer comprising a metal or alloy. The first layer may define an internal surface of the multilayer liner, and the multilayer liner may define a substantially closed internal volume.

In some examples, the disclosure describes a system including a chemical vapor deposition furnace; a multilayer liner for the chemical vapor deposition furnace. The multilayer liner may include a first layer comprising graphite and a second layer comprising a metal or alloy. The first layer may define an internal surface of the multilayer liner, and the multilayer liner may define a substantially closed internal volume.

In some examples, the disclosure describes a method including heating a substrate and a coating material within a chemical vapor deposition furnace. The substrate and the coating material may be disposed within a substantially closed internal volume defined by a multilayer liner disposed within the chemical vapor deposition furnace. The coating material may deposit on a surface of the substrate during the heating. The multilayer liner may include a first layer comprising graphite and a second layer comprising a metal or alloy, and the first layer may define an internal surface of the multilayer liner

The details of one or more examples are set forth in the accompanying drawings and the description below. Other features, objects, and advantages will be apparent from the description and drawings, and from the claims.

### BRIEF DESCRIPTION OF DRAWINGS

FIG. 1 is a conceptual and schematic block diagram illustrating an example system including a chemical vapor deposition furnace and a multilayer liner.

### DETAILED DESCRIPTION

The disclosure describes a multilayer liner for a CVD furnace, a pack cementation furnace, or the like. In some examples, the multilayer liner may include a graphite layer and a metal or alloy layer. In some examples, the metal or alloy layer may include an element included in the substrate-to-be-coated. For example, the metal or alloy layer may include the element on which the substrate is based (e.g., the element present in the substrate in the largest concentration). As an example, if the substrate-to-be coated is a Ni-based alloy, the metal or alloy layer may include Ni or an alloy including Ni. The combination of the graphite layer and the metal or alloy layer may reduce or substantially prevent a contaminant species from the furnace from being incorporated in the coating formed during the CVD process, e.g., compared to a liner including only one of a graphite layer or a metal or alloy layer.

In some examples, the multilayer liner may be modular, such that the multilayer liner may be removed from the CVD furnace without disassembling the CVD furnace. This may facilitate replacement or exchange of one or more layers of the multilayer liner with another layer or another multilayer liner.

In contrast to a crucible, which is open to the surrounding atmosphere, the multilayer liner may define an internal volume that is substantially closed to the atmosphere within the CVD furnace. For example, the multilayer liner may include a two part container including a body and a cover. In some examples, the cover may be friction fit to the body of the multilayer liner. The contact between the cover and the body may or may not form a gas tight seal. In some examples, the contact between the cover and the body does not form a gas tight seal. However, when the furnace is heated during the CVD process, the solid coating precursors present within the volume defined by the multilayer liner vaporize, forming a positive pressure within the volume defined by the multilayer liner. This may reduce movement of gas from within the CVD furnace and outside of the internal volume on the multilayer liner into the internal volume of the multilayer liner, reducing or substantially eliminating incorporation of one or more elements from the furnace being incorporated into the coating.

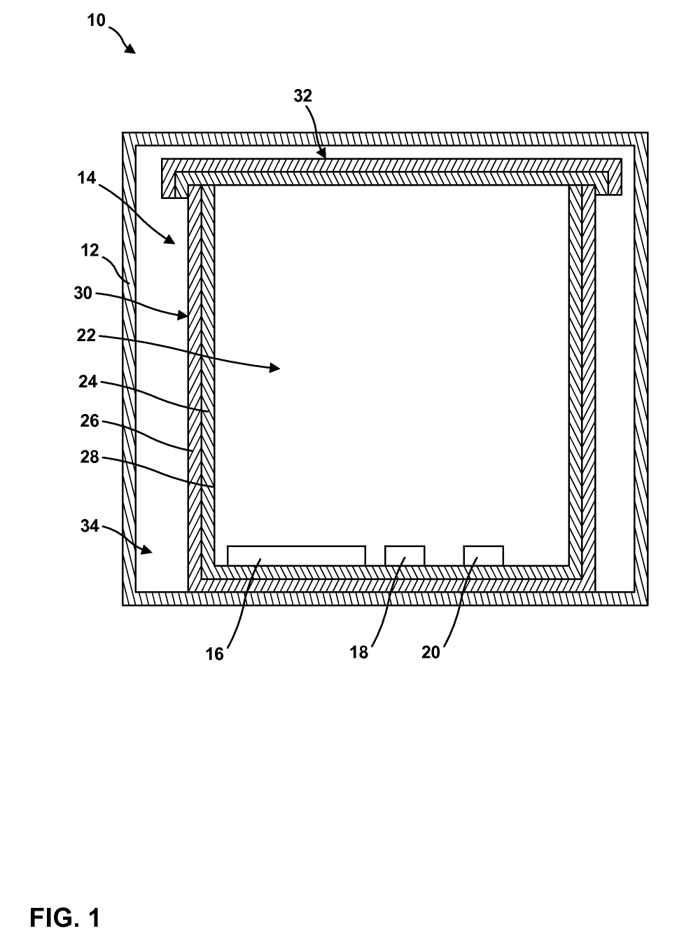

FIG. 1 is a conceptual and schematic block diagram illustrating an example system 10 including a CVD furnace 12 and a multilayer liner 14. A substrate 16, a coating material 18, and an activator 20 are enclosed by multilayer liner 14 in the internal volume 22 of multilayer liner 14.

CVD furnace 12 may be any furnace or other heating chamber capable of heating substrate 16, coating material 18, and activator 20 to temperatures used in the static CVD process. In some examples, CVD furnace 12 may include a fluid inlet and a fluid outlet that allow retort CVD furnace 12 to be purged of air and backfilled with an inert gas prior to heating. For example, CVD furnace 12 may be purged of air using a vacuum pump and filled with argon. CVD furnace 12 then may be purged of the argon with the vacuum pump and filled with fresh argon. This process may be performed one or more times to limit the concentration of oxygen within internal volume 22 of multilayer liner 14.

In some example, CVD furnace 12 may be formed of or include an element that is not included in the coating material 18. The element in CVD furnace 12 that is not included in coating material 18 may not be included in the coating formed on substrate 16 during the CVD process. To the contrary, in some examples, the element in CVD furnace 12 may have detrimental effects if incorporated into the coating. For example, CVD furnace 12 may include iron, and iron may have detrimental effects if incorporated into an aluminide coating including beta NiAl phase, gamma-prime Ni₃A1 phase, or both. The multilayer liner 14 described herein may reduce or substantially eliminate incorporation of an element or elements from CVD furnace 12 in a coating on substrate 16.

Substrate 16 may be a component to be coated using a CVD technique. In some examples substrate 16 includes a metal or alloy, such as a superalloy. Example superalloys include Ni-based superalloys, Ti-based superalloys, Co-based superalloys, or the like. In some examples, substrate 16 may be a component of a high temperature mechanical system, such as a component of a gas turbine engine. Example components include gas turbine blades or vanes.

Coating material 18 may include one or more elements, alloys, or compounds that are to be deposited on substrate 16 during the CVD technique to form a coating. As an example, a coating deposited using a CVD technique may include gamma-prime Ni₃A1 and beta phase NiAl discrete dual regions, such as a beta NiAl phase layer is disposed on a gamma-prime Ni₃Al phase layer. In some examples, one or both phase layers may be modified by at least one a platinum group metal; at least one reactive element such as hafnium, yttrium, zirconium, chromium, or silicon; or both. The platinum group metal and reactive element may enhance hot corrosion resistance and thermal barrier characteristics. An example coating may include a lower layer that includes between about 15 atomic percent (at. %) and about 25 at. % aluminum, between about 5 at. % and about 15 at. % platinum, between about 0.1 weight percent (wt. %) and about 0.3 wt. % hafnium, and a balance other elements, including nickel. The example coating may include an upper layer that includes between about 35 at. % and about 40 at. % aluminum, between about 15 at. % and about 20 at. % platinum, between about 0.1 wt. % and about 0.2 wt. % hafnium, and a balance other elements, including nickel.

In some examples, coating constituents may be deposited simultaneously or co-deposited during the coating process. In other examples, coating constituents may be deposited sequentially. In other examples, a portion of the coating elements can be simultaneously deposited and another portion of the coating elements can be sequentially deposited. Simultaneous or sequential deposition can be utilized to provide a selected coating composition.

Some examples of coating operations using CVD furnace 12 can include: co-deposition of aluminum and a reactive element; chromium deposition followed by co-deposition of aluminum and a reactive element; hafnium deposition followed by co-deposition of aluminum and a reactive element; chromium deposition, followed by reactive element deposition, followed by aluminum deposition; silicon deposition followed by co-deposition of aluminum and a reactive element; and silicon deposition, followed by reactive element deposition, followed by aluminum deposition

In examples in which coating material 18 includes more than one coating constituent, coating material 18 may include an alloy of the coating constituents. Alternatively, multilayer liner 14 may enclose two or more separate coating materials 18, each of which is a separate physical source for one or more of the coating constituents. For example, coating material 18 may include an Al—Cr alloy, as described above, which may be a physical source for both Al and Cr. As another example, a first coating material 18 may include a first physical source for a first coating element (e.g., Al) and a second coating material 18 may include second physical source for a second coating material (e.g., Cr). Continuing the example, the first and second physical sources may be physically separate from each other within multilayer liner 14. Coating material 18 may be a powder or other solid source, such as a block or pellet, of the coating elements and/or compounds.

Activator 20 may include a halide species that reacts with coating material 18 to form a donor-halogen compound (e.g., a halide of a donor, such as AlCl₃). The donor-halogen compound may be formed from a solid-gas reaction between solid coating material 18 and a gas phase activator 20, which has sublimated or evaporated under heating. The donor-halogen compound may also be formed by a gas phase reaction between coating material 18 that has evaporated or sublimated and activator 20, which has also evaporated or sublimated. In some examples, activator 20 may include NH₄Cl, HCl, (NH₄)HF₂, or another halide salt.

In some examples, coating material 18 and activator 20 may not be separate, but may instead include a solid donor-halogen compound. For example, the donor-halogen compound may include a solid aluminum halide, such as AlCl₃, a reactive element halide, a silicon halide, or a chromium halide. The solid donor-halogen compound may be a powder, pellet, block, or the like.

As illustrated in FIG. 1, in some examples, coating material 18 and activator 20 may not be in contact with substrate 16. This may facilitate the use of CVD to coat a surface of an interior cavity of an article, such as, for example, a turbine blade or vane. In some examples, the vapor phase donor-halogen compound may be directed to the interior cavity of the article by an apparatus, such as a piping system or the like.

Substrate 16, coating material 18, and activator 20 are disposed within the internal volume 22 of multilayer liner 14. Multilayer liner 14 may include a plurality of layers. In the example illustrated in FIG. 1, multilayer liner 14 includes a first layer 24 and a second layer 26. In other examples, multilayer liner 14 may include more than two layers. In general, multilayer liner 14 may include at least two layers.

First layer 24 of multilayer liner 14 may include graphite. First layer 24 defines an inner surface 28 of multilayer liner 14 Inner surface 28 of multilayer liner 14 defines internal volume 22 defined by multilayer liner 14. Graphite may be substantially inert to chemical species used in the CVD technique (e.g., substrate 16, coating material 18, and activator 20), and may not generate vapor at the temperatures used during the CVD technique.

Second layer 26 of multilayer liner 14 may include a metal or alloy. In some examples, second layer 26 may include a constituent of substrate 16. For example, second layer 26 may include an element or compound that is most prevalent in substrate 16 (e.g., an element or compound on which substrate 16 is based). For example, when substrate 16 includes a Ni-based superalloy, second layer 26 may include nickel. In some examples, second layer 26 may consist of the element or compound that is most prevalent in substrate 16. For example, second layer 26 may consist of nickel when substrate 16 is a nickel-based alloy.

In some examples, instead of first layer 24 including graphite and second layer 26 including a metal or alloy, first layer 24 may include the metal or alloy and second layer may include graphite. Utilizing a multilayer liner 14 with a first layer including graphite 24 may reduce contamination of first layer 24 with coating constituents, which may allow use of a single multilayer liner 14 for different coating compositions.

The walls of first layer 24 and second layer 26 may define any thickness, and the thickness of each respective wall may be the same as or different than the thickness of any other respective wall of first layer 24 and second layer 26. In some examples, each wall of first layer 24 and second layer 26 may define a thickness greater than or equal to about 1 millimeter.

In some examples, the outer surfaces of first layer 24 may contact the inner surfaces of second layer 26. For example, first layer 24 may be friction fit against second layer 26. In other examples, first layer 24 may rest within the internal volume defined by second layer 26, e.g., there may be space between at least one of the walls of first layer 24 and the corresponding wall of second layer 26. Regardless of whether first layer 24 and second layer 26 are tightly fit or loosely fit, in some examples, first layer 24 may be removable from second layer 26 so that first layer 24 and second layer 26 may be individually replaceable or repairable.

Multilayer liner 14 may be modular, e.g., may be removable from CVD furnace 12. For example, multilayer liner 14 may be a removable insert that can be inserted and removed from the interior of CVD furnace 12. This may facilitate using different multilayer liners 14 for different substrates 16 and/or coating materials 18, repair or replacement of multilayer liner 14, or the like.

In the example illustrated in FIG. 1, multilayer liner 14 includes a body 30 and a cover 32. Each of body 30 and cover 32 includes multiple layers (e.g., first layer 24 and second layer 26). In some examples, cover 32 may be friction fit on body 30 (e.g., a surface of cover 32 intimately contacts a surface of body 30 to retain cover 32 relative to body 30). A multilayer liner 14 including body 30 and cover 32 may facilitate insertion and removal of substrate 16, coating material 18, and activator 20 in internal volume 22 of multilayer liner 14.

During the CVD technique, CVD furnace 12 may heat the internal volume 34 of CVD furnace 12, including multilayer liner 14, substrate 16, coating material 18, and activator 20 to a predetermined temperature. In some examples, the predetermined temperature may be between about 1500° F. (about 815° C.) and about 1900° F. (about 1038° C.). For example, the temperature can be between about 1600° F. (about 871° C.) and about 1800° F. (about 982° C.). At the predetermined temperature, activator 20 may react with coating material 18 and form a vapor phase halide including the coating material 18. The formation of the vapor phase halide may produce a positive pressure differential between internal volume 22 of multilayer liner 14 and internal volume 34 of CVD furnace 12, which may reduce movement of gas from internal volume 34 of CVD furnace 12 to internal volume 22 of multilayer liner 14.

Reducing gas movement from internal volume 34 of CVD furnace 12 to internal volume 22 of multilayer liner 14 may reduce incorporation of one or more elements from CVD furnace 12 into the coating formed on substrate 16. When CVD furnace 12 is heated, some of the vaporized activator 20 may remain unreacted with coating material 18, and may instead escape from internal volume 22 of multilayer liner 14 (e.g., through space between body 30 and cover 32). This vaporized activator 20 may react with CVD furnace 12 to form a vapor phase halide with an element from CVD furnace 12 (e.g., iron). Without the positive pressure inside internal volume 22 of multilayer liner 14 compared to internal volume 34 of CVD furnace 12, the vapor phase iron halide may travel to the surface of substrate 16 and iron may be incorporated into the coating being formed on substrate 16 during the CVD technique. With positive pressure inside internal volume 22 of multilayer liner 14 compared to internal volume 34 of CVD furnace 12, the rate at which the vapor phase iron halide travels to the surface of substrate may be reduced, and incorporation of iron into the coating being formed on substrate 16 during the CVD technique may be reduced or substantially eliminated (e.g., eliminated or nearly eliminated).

The multilayer liner 14 also may reduce or substantially eliminate diffusion of elements or halides through the walls of multilayer liner 14, e.g., compared to a liner including a single layer. This may contribute to reducing or substantially eliminating incorporation of one or more elements from CVD furnace 12 into the coating being formed on substrate 16 during the CVD technique. In these ways, utilizing a multilayer liner 14 including at least one graphite layer and at least one layer including a metal or alloy may reduce or substantially eliminate incorporation of impurities from the CVD furnace 12 into the coating being formed on substrate 16 during the CVD process.

Although the preceding examples were described with reference to CVD furnace 12 and a CVD technique, in other examples, multilayer liner 14 may be used in a pack cementation furnace and for a pack cementation coating technique. In a pack cementation coating technique, the internal volume 22 of multilayer liner 14 may be at least partially filled with a mixture of a coating material, an activator, a filler, and the substrate to be coated. The remaining coating steps (e.g., evacuating air and backfilling with an inert gas, heating, and the like) in a pack cementation technique may be similar to the steps described above with respect to a CVD technique.

### EXAMPLES

### Comparative Example 1

More than ten samples were prepared in which a coating was formed on a Ni-based superalloy substrate using a CVD process. The Ni-based superalloy was available under the trade designation CMSX-4® from Cannon-Muskegon Corporation, Muskegon, Mich. The CVD furnace included only an iron-based superalloy liner.

The coating was formed using a single CVD step from an Al-56Cr alloy aluminum donor, a HfCl₄ hafnium donor, and a NH₄Cl activator. The CVD process parameters were a temperature of about 1600° F., about 5 hours, and a pressure of about 1 atmosphere. The coating material did not include iron. The coating formed on the substrate included between about 2 and about 21 atomic percent iron.

### Comparative Example 2

A coating was formed on a Ni-based superalloy substrate using a CVD process. The Ni-based superalloy was available under the trade designation CMSX-4® from Cannon-Muskegon Corporation, Muskegon, Mich. The CVD furnace included only a 0.125 inch thick graphite liner.

The coating was formed using a single CVD step from an Al-56Cr alloy aluminum donor, a HfCl₄ hafnium donor, and a NH₄Cl activator. The CVD process parameters were a temperature of about 1600° F., about 5 hours, and a pressure of about 1 atmosphere. The coating material did not include iron. When the first sample was prepared, the coating formed on the substrate of the first sample included less than about 1 atomic percent iron. After about 10 samples prepared sequentially in the CVD furnace, coatings included greater than about 10 atomic percent iron.

### Comparative Example 3

A coating was formed on a Ni-based superalloy substrate using a CVD process. The Ni-based superalloy was available under the trade designation CMSX-4® from Cannon-Muskegon Corporation, Muskegon, Mich. The CVD furnace included only a 0.125 inch thick nickel liner.

The coating was formed using a single CVD step from an Al-56Cr alloy aluminum donor, a HfCl₄ hafnium donor, and a NH₄Cl activator. The CVD process parameters were a temperature of about 1600° F., about 5 hours, and a pressure of about 1 atmosphere. The coating material did not include iron. When the first sample was prepared, the coating formed on the substrate included less than about 1 atomic percent iron. After about 10 samples prepared sequentially in the CVD furnace, coatings included greater than about 10 atomic percent iron.

### Example 1

A coating was formed on a Ni-based superalloy substrate using a CVD process. The Ni-based superalloy was available under the trade designation CMSX-4® from Cannon-Muskegon Corporation, Muskegon, Mich. The liner of the CVD furnace included a 0.125 inch thick nickel outer layer formed of Ni-200 (an alloy including at least 99% Ni, at most 0.4% Fe, at most 0.15% C, at most 0.35% Mn, at most 0.35% Si, at most 0.25% Cu, and at most 0.01% S) and a 0.125 inch thick graphite inner layer.

The coating was formed using a single CVD step from an Al-56Cr alloy aluminum donor, a HfCl₄ hafnium donor, and a NH₄Cl activator. The CVD process parameters were a temperature of about 1600° F., about 5 hours, and a pressure of about 1 atmosphere. The coating material did not include iron. A coating was formed on a substrate using a CVD process. The CVD furnace included a dual layer liner including a graphite layer and a nickel layer. The graphite layer defined the internal surface of the liner. The coating material did not include iron. Initially, the coating formed on the substrate included less than about 0.15 atomic percent iron. After about 10 cycles, the coating formed on the substrate included less than about 0.15 atomic percent iron.

Various examples have been described. These and other examples are within the scope of the following claims.

1. A multilayer liner for a chemical vapor deposition furnace, the multilayer liner comprising:
a first layer comprising graphite; and
a second layer comprising a metal or alloy, wherein the first layer defines an internal surface of the multilayer liner, and wherein the multilayer liner defines a substantially closed internal volume.

2. The multilayer liner of claim 1, further comprising a body and a cover, wherein each of the body and the cover comprises a first layer comprising graphite and a second layer comprising the metal or alloy.

3. The multilayer liner of claim 2, wherein the body and the cover engage with a friction fit.

4. The multilayer liner of claim 1, wherein the metal or alloy comprises at least one of a Ni, Co, Ti, a Ni-based alloy, a Co-based alloy, or a Ti-based alloy.

5. A system comprising:
a chemical vapor deposition furnace; and
a multilayer liner for the chemical vapor deposition furnace, wherein the multilayer liner comprises:
a first layer comprising graphite; and
a second layer comprising a metal or alloy,
wherein the first layer defines an internal surface of the multilayer liner, and
wherein the multilayer liner defines a substantially closed internal volume.

6. The system of claim 5, wherein the multilayer liner comprises a body and a cover, and wherein each of the body and the cover comprises a first layer comprising graphite and a second layer comprising the metal or alloy.

7. The system of claim 6, wherein the body and the cover engage with a friction fit.

8. The system of claim 5, wherein the metal or alloy comprises at least one of a Ni, Co, Ti, a Ni-based alloy, a Co-based alloy, or a Ti-based alloy.

9. The system of claim 8, further comprising a substrate within the closed volume defined by the multilayer liner, wherein the substrate comprises the same metal or alloy that the second layer of the multilayer liner comprises.

10. The system of claim 9, wherein the substrate comprises a Ni-based alloy, and wherein the second layer of the liner comprises a Ni-based alloy.

11. The system of claim 5, further comprising a coating material disposed in the substantially closed volume of the multilayer liner, and wherein a wall of the chemical vapor deposition furnace comprises an element not present in the coating material.

12. The system of claim 5, further comprising a positive pressure difference between the substantially closed internal volume of the multilayer liner and an internal volume of the chemical vapor deposition furnace.

13. A method comprising:
heating a substrate and a coating material within a chemical vapor deposition furnace, wherein the substrate and the coating material are disposed within a substantially closed internal volume defined by a multilayer liner disposed within the chemical vapor deposition furnace, wherein the coating material deposits on a surface of the substrate during the heating, wherein the multilayer liner comprises a first layer comprising graphite and a second layer comprising a metal or alloy, and wherein the first layer defines an internal surface of the multilayer liner.

14. The method of claim 13, wherein the coating material comprises a solid donor-halogen compound.

15. The method of claim 13, wherein heating the substrate and the coating material within the chemical vapor deposition furnace comprises heating the substrate, the coating material, and an activator within the chemical vapor deposition furnace.

16. The method of claim 13, wherein, while heating the substrate and the coating material within the chemical vapor deposition furnace, a positive pressure difference between the substantially closed internal volume of the multilayer liner and internal volume of the chemical vapor deposition furnace develops.

17. The method of claim 13, wherein the metal or alloy comprises at least one of a Ni, Co, Ti, a Ni-based alloy, a Co-based alloy, or a Ti-based alloy.

18. The method of claim 17, wherein the substrate comprises the same metal or alloy that the second layer of the multilayer liner comprises.

19. The method of claim 18, wherein the substrate comprises a Ni-based alloy, and wherein the second layer of the liner comprises a Ni-based alloy.

20. The method of claim 13, wherein a wall of the chemical vapor deposition furnace comprises an element not present in the coating material.
